(19) United States
(12) Patent Application Publication
(10) Pub. No.: US 2025/0003057 A1
(43) Pub. Date: Jan. 2, 2025

(54) SEMICONDUCTOR MANUFACTURING SOURCE PRECURSOR DELIVERY SYSTEM

(71) Applicant: ENTEGRIS, INC., Billerica, MA (US)

(72) Inventors: Weihang Guan, Livingston, NJ (US); Sanado Barolli, Bethlehem, CT (US); Ying Tang, Brookfield, CT (US); Edward E. Jones, Woodbury, CT (US); Kavita R. Murthi, Fremont, CA (US); Sharona R. Kay, White Plains, NY (US)

(21) Appl. No.: 18/754,112

(22) Filed: Jun. 25, 2024

Related U.S. Application Data
(60) Provisional application No. 63/523,638, filed on Jun. 27, 2023.

(51) Int. Cl. C23C 14/48; C23C 14/54; H01L 21/265; H01L 21/66

(52) U.S. Cl. CPC C23C 14/48; C23C 14/54; H01L 21/26513; H01L 22/20

(57) ABSTRACT

A delivery system for delivering a vaporized source precursor in ion implantation, including: an assembly including: a vessel having an interior volume and configured to produce the vaporized source precursor; a first heater to heat the vessel; and a manifold configured to control the output of the vaporized source precursor to an ion implantation device, wherein the assembly is configured to be disposed upstream of the source inlet flange.

### CROSS-REFERENCE TO RELATED APPLICATIONS

This application claims the benefit under 35 USC 119 of U.S. Provisional Patent Application No. 63/523,638, filed Jun. 27, 2023, the disclosure of which is hereby incorporated herein by reference in its entirety.

### FIELD

This disclosure relates generally to semiconductor manufacturing. More particularly, this disclosure relates to delivery of a liquid or solid precursor for semiconductor manufacturing equipment such as an ion implantation device.

### BACKGROUND

Vaporizers for liquid or solid precursors generally leverage conductive heating from metallic vessel surfaces to the liquid or solid precursor. To disperse heat through the liquid or solid precursor, an internal structure can be utilized to provide thermal pathways for the heat.

### SUMMARY

In some embodiments, a delivery system includes a vessel. In some embodiments, the vessel includes an interior volume. In some embodiments, the vessel is configured to hold a source precursor. In some embodiments, a thermal control system surrounds the vessel and is configured to heat or cool the vessel. In some embodiments, the delivery system includes a manifold. In some embodiments, the manifold is configured to be heated or cooled. In some embodiments, the manifold is configured to output a vaporized source precursor.

In some embodiments, a delivery system for delivering a vaporized source precursor in ion implantation includes an assembly. In some embodiments, the assembly includes a vessel having an interior volume and configured to produce the vaporized source precursor. In some embodiments, the assembly includes a thermal control system surrounding at least a portion of the vessel. In some embodiments, the assembly includes a manifold configured to control output of the vaporized source precursor to an ion implantation device. In some embodiments, the assembly is dimensioned to be disposed in a gas box connected to the ion implantation device.

In some embodiments, the thermal control system is configured to provide sufficient energy to the interior volume of the vessel to vaporize the source precursor. In one embodiment, the thermal control system includes a controller and a heater. In some embodiments, the thermal control system includes a controller and a plurality of heaters. The thermal control system may include multiple controllers and multiple heaters. The thermal control system may include a cooler to cool components of the system.

In some embodiments, the delivery system includes the source precursor. In some embodiments, the source precursor includes solid or liquid-phase metal halides, organometallic compounds, or combinations thereof, or other metal containing compounds.

In some embodiments, the manifold includes a housing. In some embodiments, the housing includes: a plurality of remotely controllable valves; a flow control device; and a pressure transducer. In some embodiments, the flow control device and the pressure transducer are configured to control the plurality of remotely controllable valves to provide a set flow rate of the vaporized source precursor from the manifold. In some embodiments, the flow control device includes a valve. In some embodiments, the flow control device includes a mass flow controller. In various embodiments, pressure sensing devices include a pressure sensor, a temperature sensor, a pressure transducer, etc.

In some embodiments, the delivery system includes a thermal control system connected in electronic communication with a flow control device e.g., a Mass Flow Controller, and the pressure transducer. In some embodiments, the thermal control system is configured to adjust an output of the heating components based on a value received from a mass flow controller or a pressure transducer.

In some embodiments, the delivery system includes a conduit fluidly connecting the vessel and the manifold. In some embodiments, the conduit is heated with a heater. The heater may be a heating jacket, fire rods, a heat pad, a radiation heater, an oven, heat tape, etc.

In some embodiments, the delivery system is configured to be disposed upstream of the source inlet flange, such as in the high voltage terminal and/or gas box.

In some embodiments, the vessel further includes a pneumatic valve. In some embodiments, the pneumatic valve is configured to be remotely controlled to operate between a flow enabled state and a flow disabled state.

In some embodiments, a system includes a delivery system. In some embodiments, the delivery system includes a vessel. In some embodiments, the vessel includes an interior volume. In some embodiments, the vessel is configured to hold a source precursor. In some embodiments, a heater surrounds the vessel and is configured to heat the vessel. In some embodiments, a manifold is configured to be heated. In some embodiments, the manifold is configured to control the output of a vaporized source precursor.

In some embodiments, an ion implantation system includes an ion implantation device and a gas box connected in fluid communication with the ion implantation device. In some embodiments, the gas box is configured to deliver a vaporized source precursor to the ion implantation device. In some embodiments, a delivery system is disposed in the gas box. In some embodiments, the delivery system is configured to provide the vaporized source precursor to the ion implantation device. In some embodiments, the delivery system includes an assembly that includes a vessel that includes an interior volume and is configured to hold a source precursor. In some embodiments, a thermal control system at least partially surrounds the vessel and is configured to heat the vessel. In some embodiments, a manifold is configured to be heated and is configured to output the vaporized source precursor to the ion implantation device. In some embodiments, the vaporized source precursor is provided at a purity level of at least 95%. In some embodiments, the vaporized source precursor is provided at a purity level of at least 99%. Vapor purity is defined as the percentage of a specific gas in the vapor phase at target operation temperature. In some embodiments, volatiles having a vaporization temperature within 20 deg C of target temperature on a volume basis determine the purity.

In some embodiments, the system includes the source precursor. The precursor may be a reagent. The source precursor may be a solid at standard room temperature and pressure. In some embodiments, the source precursor is a liquid at standard room temperature and pressure.

In some embodiments, the system includes a gas box. In some embodiments, the delivery system is configured to be installed within the gas box. Locating the delivery system in the gas box provides a number of benefits including allowing larger volumes of precursor to be loaded into the system at a given time which may reduce system downtime. Locating the delivery system in the gas box may improve response time, flow stability, purity, material utilization efficiency, and/or provide other benefits over previous designs.

In some embodiments, the vessel further includes a control valve, e.g. a pneumatic valve. In some embodiments, the control valve is configured to be remotely controlled to operate between a flow enabled and a flow disabled state. In one embodiment, the control valve is a high temperature rated valve.

In some embodiments, the delivery system further includes a radio frequency identification (RFID) tag and the gas box includes an RFID reader. In some embodiments, the RFID reader is configured to validate the RFID tag matches a defined value or set of values. In one embodiment, failure to validate the RFID tag may prevent heating the vessel containing the source precursor. In some embodiments, failure to validate the RFID tag may prevent actuation of a valve to a flow enabled state. In some embodiments, validation of the RFID tag is required to flow the source precursor to the ion implantation device. In one embodiment, failure to validate the RFID tag triggers an alert. The alert may be provided to a user of the system. The alert may be provided to a controller.

The vessel may include an identifying component and the delivery system may include an identifier for the identifying component. In some embodiments, the identifying component is an RFID tag. However, other identifying components may be used, for example, a magnet, a mechanical interlock, a chip, a form of data storage, a QR code, a pin pattern, etc. The identifier is capable of detecting and reading the information in the identifying component. Suitable examples include but are not limited to an RFID reader.

In some embodiments, the vessel further includes a control valve, e.g., a pneumatic valve. In some embodiments, the control valve is configured to be remotely controlled to operate between a flow enabled state and a flow disabled state.

In some embodiments, the manifold includes a housing. In some embodiments, the housing includes a plurality of pneumatic valves; a flow control device; and/or a pressure transducer. In some embodiments, the flow control device and the pressure transducer are configured to control the plurality of pneumatic valves to provide a set flow rate of the vaporized source precursor from the manifold. In some embodiments, a pressure transducer could be replaced with a single or a plurality of pressure/vacuum switches. In some embodiments, a delivery system includes a liquid or solid source precursor. In some embodiments, the source precursor includes: dimethyl hydrazine, trimethyl aluminum (TMA), hafnium chloride (HfCl₄), zirconium chloride (ZrCl₄), indium trichloride, aluminum trichloride (AlCl₃), titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), or decaborane. In some embodiments, the source precursor includes tetrafluoroborates containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments, the precursor includes volatile metallic compounds containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments: precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), or hafniumtertiarybutoxide (Hf(tOBu)₄) are used. In some embodiments the precursor consists of fluorinated xenon including but not limited to: xenon difluoride (XeF₂), xenon tetrafluoride (XeF₄), or xenon hexafluoride (XeF₆). Formations of molybdenum including, but not limited to, MoO₂Cl₂, MoO₂, MoOCl₄,MoCl₅, Mo(CO)₆, formations of tungsten including, but not limited to, WCl₅ and WCl₆, W(CO)₆, or compatible combinations and mixtures of two or more of the foregoing. In some embodiments, the delivery system includes a vessel. In some embodiments, the vessel includes an interior volume. In some embodiments, the vessel is configured to hold the source precursor. In some embodiments, a heater jacket surrounds the vessel and is configured to heat the vessel. In some embodiments, a manifold is configured to be heated. In some embodiments, the manifold is configured to output a vaporized source precursor. In some embodiments, the manifold includes a housing that includes a plurality of pneumatic valves; a mass flow controller; and a pressure transducer. In some embodiments, the mass flow controller is configured to control the plurality of pneumatic valves to provide a set flow rate of the vaporized source precursor from the manifold.

In some embodiments, a delivery system is configured to deliver a vaporized source precursor to an ion implantation device. In some embodiments, a delivery system includes a liquid or solid source precursor. In some embodiments, the source precursor includes: dimethyl hydrazine, trimethyl aluminum (TMA), hafnium chloride (HfCl₄), zirconium chloride (ZrCl₄), indium trichloride, aluminum trichloride (AlCl₃), titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), or decaborane. In some embodiments, the source precursor includes tetrafluoroborates containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments, the precursor includes volatile metallic compounds containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments: precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), or hafniumtertiarybutoxide (Hf(tOBu)₄) are used. In some embodiments the precursor consists of fluorinated xenon including but not limited to: xenon difluoride (XeF₂), xenon tetrafluoride (XeF₄), or xenon hexafluoride (XeF₆). Formations of molybdenum including, but not limited to, MoO₂Cl₂, MoO₂, MoOCl₄,MoCl₅, Mo(CO)₆, formations of tungsten including, but not limited to, WCl₅ and WCl₆, W(CO)₆, or compatible combinations and mixtures of two or more of the foregoing.

In some embodiments, the assembly includes a vessel having an interior volume and configured to produce the vaporized source precursor. In some embodiments, a heater jacket surrounds at least a portion of the vessel and is configured to heat the vessel. In some embodiments, the assembly includes a manifold configured to be heated and configured to output the vaporized source precursor to the ion implantation device. In some embodiments, the vaporized source precursor is provided at a vapor purity level of at least 99%. In some embodiments, the manifold includes a housing including a plurality of pneumatic valves; a mass flow controller; and a pressure transducer. In some embodiments, the mass flow controller is configured to control the plurality of pneumatic valves to provide a set flow rate of the vaporized source precursor from the manifold.

### BRIEF DESCRIPTION OF THE DRAWINGS

References are made to the accompanying drawings that form a part of this disclosure and that illustrate embodiments in which the systems and methods described in this Specification can be practiced.

FIG. 1 is a schematic diagram of a system for use in a semiconductor manufacturing process, according to some embodiments.

FIG. 2 is a schematic diagram of a delivery system, according to some embodiments.

FIG. 3 shows a perspective view of an example of the delivery system of FIG. 2, according to some embodiments.

FIG. 4 shows a sectional view of the example of the delivery system of FIG. 3, according to some embodiments.

FIG. 5 shows a perspective view of an example of the delivery system of FIG. 3, according to some embodiments.

FIG. 6 shows a schematic flow diagram of the delivery system of FIG. 3, according to some embodiments.

FIG. 7 shows a section view of a feedthrough design for a delivery system, according to some embodiments.

FIG. 8 shows a section view of a feedthrough design for a delivery system, according to some embodiments.

FIG. 9 shows a section view of a feedthrough design for a delivery system, according to some embodiments.

FIG. 10 shows a section view of a feedthrough design for a delivery system, according to some embodiments.

FIG. 11 shows a section view of a feedthrough design for a delivery system, according to some embodiments.

Like reference numbers represent the same or similar parts throughout.

### DETAILED DESCRIPTION

Embodiments of this disclosure relate to systems and methods for volatilization of source precursors to produce vapor for fluid-utilizing processes such as chemical vapor deposition or ion implantation.

Embodiments of this disclosure can be applied with various types of source precursors, including solid form source precursor materials, liquid form source precursor materials, semi-solid from source precursor materials, slurry form source precursor materials (including solid materials suspended in a liquid), and solutions of solid materials dissolved in a solvent. In some embodiments, solid form source precursor materials may, for example, be in the form of powders, granules, pellets, beads, bricks, blocks, sheets, rods, plates, films, coatings, or the like, and may embody porous or nonporous forms, as desirable in a given application.

The source precursor can include solid precursors of any suitable type. Examples of such solid precursors include, but are not limited to, solid-phase metal halides, organometallic solids, any combination thereof, or the like. In some embodiments, a delivery system includes a liquid or solid source precursor. In some embodiments, the source precursor includes: dimethyl hydrazine, trimethyl aluminum (TMA), hafnium chloride (HfCl₄), zirconium chloride (ZrCl₄), indium trichloride, aluminum trichloride (AlCl₃), titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), or decaborane. In some embodiments, the source precursor includes tetrafluoroborates containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments, the precursor includes volatile metallic compounds containing: sodium, boron, magnesium, gallium, indium, antimony, copper, phosphorous, arsenic, lithium, selenium, ruthenium, erbium, tungsten, hafnium, tin, ytterbium, platinum, or lanthanum. In some embodiments: precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), or hafniumtertiarybutoxide (Hf(tOBu)₄) are used. In some embodiments the precursor consists of fluorinated xenon including but not limited to: xenon difluoride (XeF₂), xenon tetrafluoride (XeF₄), or xenon hexafluoride (XeF₆). Formations of molybdenum including, but not limited to, MoO₂Cl₂, MoO₂, MoOCl₄,MoCl₅, Mo(CO)₆, formations of tungsten including, but not limited to, WCl₅ and WCl₆, W(CO)₆, or compatible combinations and mixtures of two or more of the foregoing.

Embodiments of this disclosure provide a storage and delivery package for use in a semiconductor manufacturing process. In some embodiments, the storage and delivery package includes a vessel and a manifold. In some embodiments, the combined vessel and manifold can be installed within a gas box of a semiconductor manufacturing system. In some embodiments, the storage and delivery package includes a heated conduit fluidly connecting the gas box and a tool in the semiconductor manufacturing system. In some embodiments, the storage and delivery package can be used to provide a vaporized source precursor to the tool in the semiconductor manufacturing system. In some embodiments, the source precursor is accordingly delivered from the gas box (and the storage and delivery package) instead of through a vaporizer onboard the tool.

In some embodiments, a larger amount of source precursor can be stored for use in the semiconductor manufacturing system than in prior systems. In some embodiments, the storage and delivery package can advantageously reduce an amount of clogging in semiconductor manufacturing systems such as, but not limited to, ion implantation systems. In some embodiments, reducing an amount of clogging can, for example, reduce an amount of time that is needed to service the systems and can reduce an overall amount of maintenance. In some embodiments, a startup time of the semiconductor manufacturing system can be reduced compared to prior systems. In some embodiments, the storage and delivery package can increase a flexibility of source precursors provided compared to prior systems. In some embodiments, the storage and delivery package can also increase a precision of the vaporized source precursor provided compared to prior systems. As a result, the storage and delivery package can, in some embodiments, improve an overall throughput from the semiconductor manufacturing systems. In some embodiments, isolating the source precursor within the storage and delivery package can also enable operators to work on the gas box or other parts of the semiconductor manufacturing system without potentially being exposed to hazardous materials as they are contained within the storage and delivery package. This may reduce environmental health and safety (EHS) risks to personnel servicing the equipment.

The described system offers a number of advantages over prior designs. For some embodiments, the system includes a larger volume of precursor in the vessel which may allow for longer periods of use between refills for the system. In some embodiments, the system provides improved flow stability of vaporized source precursor compared with previous designs. This may be due to the control of the temperature profile of the delivery path for the vaporized source precursor which reduces instances of clogging and/or condensation of the vaporized source precursor. The described valves in the manifold may improve response time allowing for more effective metering of the supplied vaporized source precursor. In some embodiments, the described system is advantageous in the purity of the vaporized source material provided. For example, the system may include a filter to reduce particulate matter. In some embodiments, the system may utilize liquid or solid precursor material more efficiently than previous designs. Similarly, the described system may reduce process contamination by avoiding condensation of the vaporized source precursor in the flow path from the vessel to the ion implanter. Particular advantages will be evident to the person of skill in the art based on the disclosed embodiments herein.

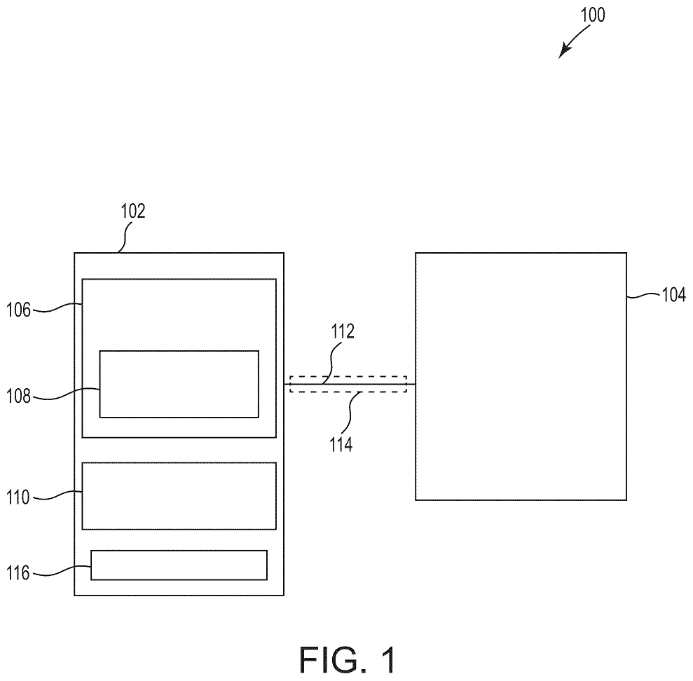

FIG. 1 is a schematic diagram of a system 100 for use in a semiconductor manufacturing process, according to some embodiments. In some embodiments, the system 100 can be an ion implantation system or the like.

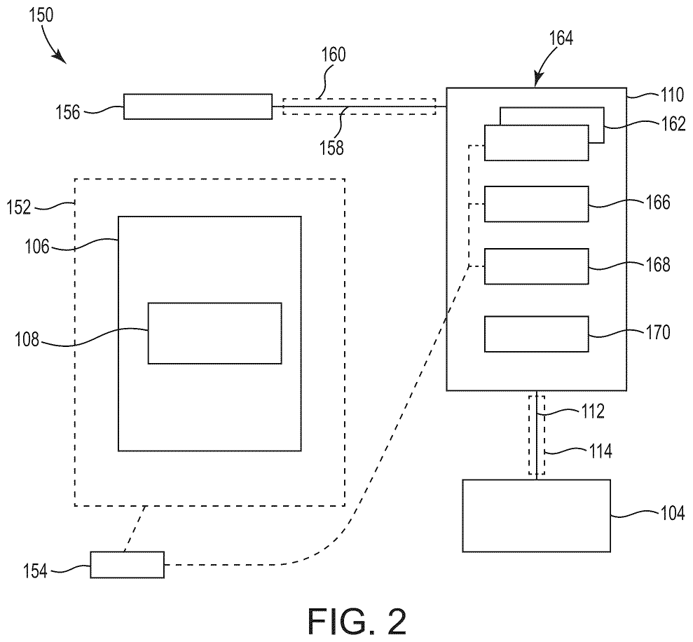

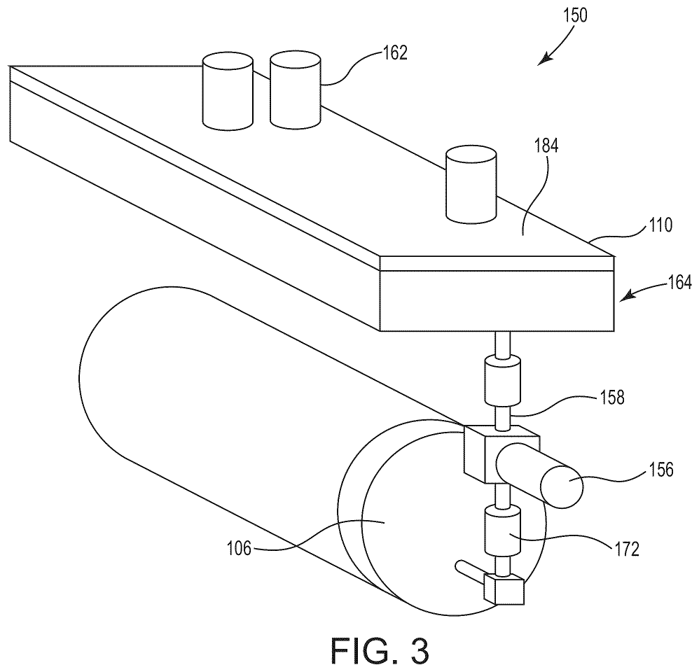

In the illustrated embodiment, the system 100 includes a gas box 102 and a tool 104. The gas box 102 can include a vessel 106 configured to include a source precursor 108. The gas box 102 can also include a manifold 110 configured to control delivery of the source precursor 108 in a vaporized form from the vessel 106 to the tool 104. The vessel 106 and the manifold 110 are shown and described in additional detail in accordance with FIG. 2 and FIG. 3 below.

A conduit 112 fluidly connects the gas box 102 and the tool 104 to provide the vaporized source precursor to the tool 104 for usage in the semiconductor manufacturing process. In some embodiments, the conduit 112 is at least partially heated using a heater 114 such as, but not limited to, a heat tape or the like. Other examples of the heater 114 include a heating jacket, fire rods, a heat pad, a radiation heater, an oven, etc.

In some embodiments, the gas box 102 includes a power supply 116. The power supply 116 is configured to be in electrical communication with various components of the package and delivery system (e.g., the delivery system 150 shown and described in additional detail in accordance with FIG. 2 below).

In some embodiments, the source precursor 108 can include liquid or solid precursors of any suitable type. Examples of such solid precursors include, but are not limited to, solid-phase metal halides, organometallic solids, any combination thereof, or the like. Examples of the source precursor that may be utilized include, but are not limited to, dimethyl hydrazine, trimethyl aluminum (TMA), hafnium chloride (HfCl₄), zirconium chloride (ZrCl₄), indium trichloride, aluminum trichloride (AlCl₃), titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), decaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), formations of molybdenum including, but not limited to, MoO₂Cl₂, MoO₂, MoOCl₄,MoCl₅, Mo(CO)₆, formations of tungsten including, but not limited to, WCl₅ and WCl₆, W(CO)₆, and compatible combinations and mixtures of two or more of the foregoing.

FIG. 2 is a schematic diagram of a delivery system 150, according to some embodiments. The delivery system 150 can include the vessel 106 and the manifold 110. In some embodiments, the delivery system can be included as an assembly of the two components (the vessel 106 and the manifold 110). In some embodiments, the delivery system 150 is installed within the gas box 102 (FIG. 1). In some embodiments, the delivery system 150 is configured to be connected in fluid communication with the tool 104 (FIG. 1) to deliver a source precursor to the tool 104 for use in the system 100 via the conduit 112 that is also temperature controlled. In some embodiments, the flow path of the source precursor from the vessel 106, through the manifold 110, to the tool 104 is characterized by a non-decreasing temperature profile such that the temperature does not drop along the flow path and thus avoids condensation or clogging from the source precursor.

In the illustrated embodiment, the delivery system includes the vessel 106 disposed within a heater 152 that surrounds the vessel 106. In some embodiments, the heater 152 is configured to distribute heat throughout the vessel 106. In some embodiments, the heater 152 can reduce a likelihood of cold spots within the vessel 106 which can, for example, cause unintended condensation and clogging of the components of the delivery system 150 or the tool 104 (FIG. 1). In some embodiments, the heater 152 can be controlled by a controller 154. In some embodiments, the controller 154 can use current temperatures measured at the vessel 106, a mass flow rate of the vaporized source precursor, a pressure of the vaporized source precursor, or combinations thereof, to control a heat output of the heater 152. The heater may include a heating jacket, fire rods, a heat pad, a radiation heater, an oven, etc. In some embodiments, the delivery system can be included as an assembly of the two components (the vessel 106 and the manifold 110).

The vessel 106 can include a pneumatic isolation valve 156 disposed at an outlet of the vessel 106. The pneumatic isolation valve 156 can be cycled between a flow enabled and a flow disabled state using the controller 154 to, for example, shut off flow of the vaporized source precursor when service is desired. In some embodiments, the pneumatic isolation valve 156 can enable rapid shutdown of the flow from the vessel 106. In some embodiments, rapid shutdown can be accompanied by flowing an inert gas into a portion of the manifold 110. This may allow the manifold 110 to cool more quickly and have inert gas rather than precursor in the manifold 110 during shut down.

As shown in the illustrated embodiment, a conduit 158 connects the vessel 106 and the manifold 110 in fluid communication. In some embodiments, the conduit 158 can include a heat tape 160. In some embodiments, the heat tape 160 is configured to reduce heat losses when the vaporized source precursor is flowing from the vessel 106 to the manifold 110. In some embodiments, the controller 154 can be used to control a heat output of the heat tape 160. In other embodiments, the conduit 158 is heated by a heater. The heater may be a heating jacket, fire rods, a heat pad, a radiation heater, an oven, etc. The heater of the conduit 158 may heat the conduit 158 to a temperature greater than a temperature of the manifold 110. The temperature of the manifold 110 may be set to a temperature greater than the temperature of the vessel 106. Thus, the flow path of the vapor from the vessel 106 may be increasing (or non-decreasing) from the vessel 106 to the manifold 110 to the conduit 158. This temperature profile may reduce condensation in the flow path.

The manifold 110 can include a plurality of pneumatic valves 162 in fluid communication with the vessel 106. The plurality of pneumatic valves 162 can be installed within a housing 164. In some embodiments, the housing 164 can be made of a heat conductive material. In some embodiments, the heat conductive material can include, but is not limited to, aluminum, graphite, or the like. In some embodiments, the housing 164 can include a solid block of material that includes channels disposed therein in which various components such as the plurality of pneumatic valves 162 are disposed. In some embodiments, the housing 164 is an aluminum block that is heated. In some embodiments, the housing 164 can also be insulated to provide for more stable temperature control. In some embodiments, the housing 164 includes a shutdown valve which provides inert gas to the housing during shut down. The use of inert gas during shutdown may decrease shutdown time and clear the housing 164 of precursor.

In some embodiments, the manifold 110 can include a mass flow controller 166. In some embodiments, the mass flow controller 166 can be used to set a particular mass flow rate to meet a corresponding demand by the tool 104 (FIG. 1). In some embodiments, the manifold 110 also includes a pressure transducer 168 to monitor conditions within the delivery system 150. In some embodiments, the mass flow controller 166 and the pressure transducer 168 can be used to control the heater jacket 152 to ensure that the source precursor 108 is maintained at an appropriate temperature to provide the desired output for the tool 104. In some embodiments, the pressure, flow rate, or combination thereof can provide a tighter control of the heater jacket 152 in a short period of time than if temperature measurements were relied upon instead. In some embodiments, the mass flow controller 166 and pressure transducer 168 are used to control various heaters along the flow path of the vaporized precursor to the tool 104.

In some embodiments, the delivery system 150 can include a radio frequency identification (RFID) tag 170. In some embodiments, the gas box (not shown) in which the delivery system 150 is installed includes an RFID reader. The RFID tag 170 can be configured to include a defined value associated with, for example, a particular type of the source precursor 108 in the vessel 106. In some embodiments, the RFID reader can be configured to ensure that the expected RFID tag 170 is installed in order for the delivery system 150 to be functional. For example, if the wrong source precursor is installed the gas box will not recognize the RFID tag and, as a result, may not allow for output of the vaporized source precursor from the gas box. In some such embodiments, an error can be generated to alert an operator of the semiconductor manufacturing equipment. In some embodiments, an unrecognized RFID tag 170 will prevent heating of the vessel 106 and/or source precursor 108.

In some embodiments, the delivery system 150 is configured to provide a vaporized source precursor at a purity level of at least 95%, at least 96%, at least 97%, at least 98%, at least 99%, at least 99.0001%, at least 99.0010%, at least 99.0100%, at least 99.1000%, at least 99.2000%, at least 99.3000%, at least 99.4000%, at least 99.5000%, at least 99.6000%, at least 99.7000%, at least 99.8000%, at least 99.9000%, at least 99.9100%, at least 99.9200%, at least 99.9300%, at least 99.9400%, at least 99.9500%, at least 99.9600%, at least 99.9700%, at least 99.9800%, or at least 99.9900%.

In some embodiments, a temperature of the vaporized source precursor output from the delivery system 150 can be from room temperature up to approximately 250° C.

In some embodiments, the delivery system 150 can include one or more temperature sensors 190 disposed to ensure that temperature parameters are being met. In some embodiments, a temperature of the vessel 106 can be less than a temperature of the manifold 110, which can be less than a temperature of the conduit 112 connected to the tool 104 (FIG. 1). This temperature profile of increasing (or non-decreasing) temperatures may reduce the tendency of the precursor to condense in the flow path from the vessel 106 to the manifold 110 to the gas line to the tool 104.

Obtaining the desired temperature profile described may depend on the temperatures measured by the temperature sensors 190 and the controller. Some temperature sensors 190 may be vulnerable to deviations from normal due to the electromagnetic field generated by the arc chamber. Accordingly, it may be necessary to adjust the response from the temperature sensors 190 based on the state of the arc chamber. This may prevent or reduce condensation of the precursor. In other embodiments, the temperature sensors 190 are located to minimize the impact of electromagnetic interference from the arc chamber. In some embodiments, the temperature sensor 190 compensates for measurement remote to the vaporized precursor to avoid direct contact between the vaporized precursor and the temperature sensor 190. For example, the temperature sensor 190 may be located in or on a wall of the vessel 106, integrated into the manifold 110, or located on an outer surface of the gas line.

FIG. 3 shows a perspective view of an example of the delivery system 150, according to some embodiments. The delivery system 150 includes the vessel 106 and the manifold 110. In the illustrated embodiment, the vessel 106 and the manifold 110 are coupled via the conduit 158. At an outlet of the vessel 106, a filter 172 can be included. In some embodiments, the filter 172 is optional. In some embodiments, the filter 172 can, for example, provide an additional prevention of particle migration out of the vessel 106. In some embodiments, the filter 172 can be located inside the vessel 106.

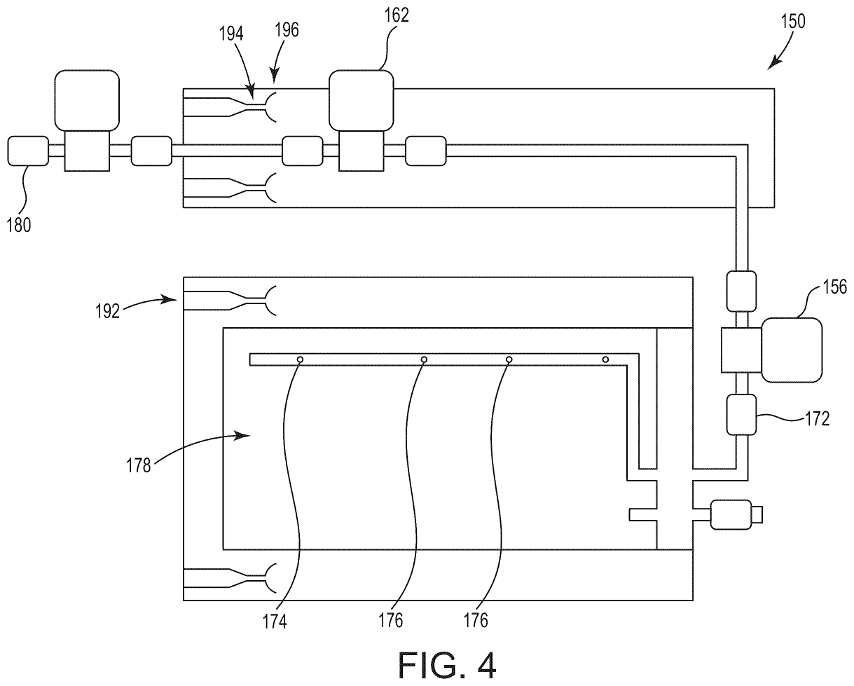

FIG. 4 shows a sectional view of the example of the delivery system 150 from FIG. 3, according to some embodiments. The vessel 106 includes a conduit 174 including a plurality of apertures 176. The conduit 174 is configured to receive the vaporized source precursor and provide it to the outlet of the vessel 106. In some embodiments, the vessel 106 can include one or more additional elements such as, but not limited to, a gasket to prevent leakage from the vessel 106. In some embodiments, the gasket can include a spring to provide additional force to improve a lifetime of the gasket in view of the thermal cycling and reduce changes of leakage from the vessel 106. In some embodiments, an interior volume 178 of the vessel 106 can be modified to include one or more trays, baffles, combinations thereof, or the like, to improve thermal conductivity and reduce likelihood of solid migration from the vessel 106. The vaporized fluid is then output from an outlet 180 and provided to the tool 104 (FIG. 1).

In some embodiments, the delivery system 150 includes an inlet 192, a nozzle 194, and a vent 196. The inlet 192, nozzle 194, and vent 196 serve to cool portions of the delivery system 150. In some embodiments, the inlet 192, nozzle 194, and vent 196 are organized into assemblies which are located in the delivery system 150. Examples of the inlet 192, nozzle 194, and vent 196 are shown in FIG. 4.

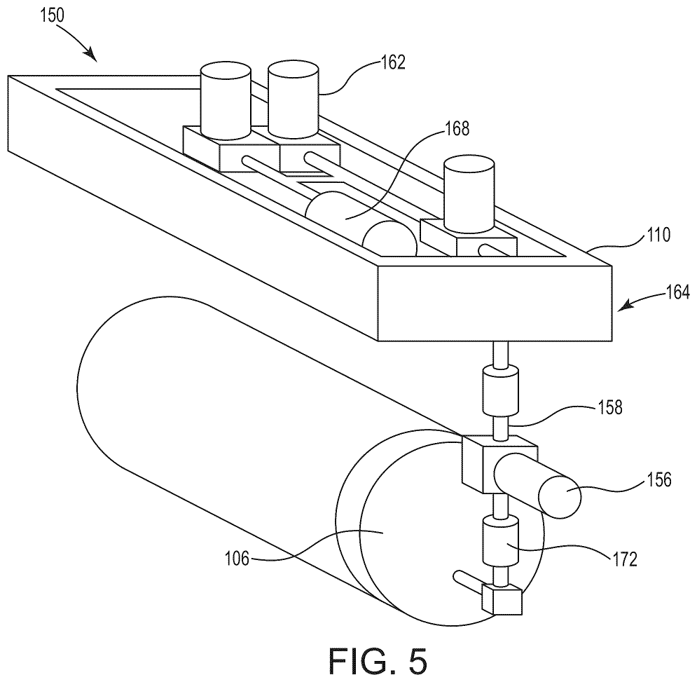

FIG. 5 shows a perspective view of an example of the delivery system 150, according to some embodiments. FIG. 5 is similar to FIG. 3, except that a portion of the housing 164 has been removed to illustrate the channels formed within the housing 164. As illustrated, the delivery system 150 includes the vessel 106 and the manifold 110. In the illustrated embodiment, the vessel 106 and the manifold 110 are coupled via the conduit 158. At an outlet of the vessel 106, a filter 172 can be included. In some embodiments, the filter 172 is optional. In some embodiments, the filter 172 can, for example, provide an additional prevention of particle migration out of the vessel 106. In some embodiments, the filter 172 can be located inside the vessel 106. As is visible in FIG. 5, the pressure transducer 168 is disposed within the housing 164.

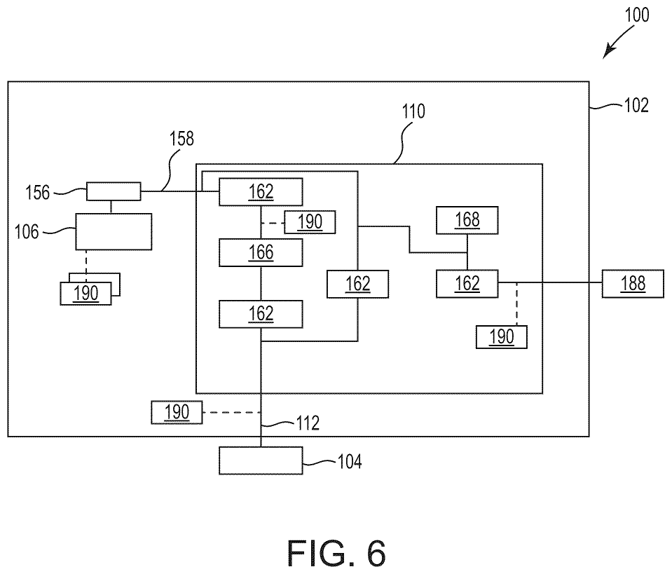

FIG. 6 shows a schematic flow diagram of the delivery system 150, according to some embodiments. As shown in FIG. 6, the delivery system 150 is configured to include the vessel 106 and the manifold 110 disposed within the gas box 102 of the system 100. The delivery system 150 is connected in fluid communication via the conduit 112 to the tool 104. Temperatures of the vessel 106, the manifold 110, and the conduit 112 are controlled to provide a temperature gradient between the vessel 106, the manifold 110, and the conduit 112 to provide a vaporized source precursor at a required temperature for the tool 104. The source precursor 108 is provided from the vessel 106 via the conduit 158 to a first and a second of the plurality of pneumatic valves 162. The first of the plurality of pneumatic valves 162 is in fluid communication with the mass flow controller 166, which is in fluid communication with a third of the plurality of pneumatic valves 162. The pressure transducer 168 is in fluid communication with the flow from the conduit 158 and a fourth of the plurality of pneumatic valves 162. The fourth of the plurality of pneumatic valves 162 is also in fluid communication with an external fluid source 188. In some embodiments, the external fluid source 188 can include a purge fluid that is used to, for example, evacuate hazardous fluids from the manifold 110. In some embodiments, the purge fluid from the external fluid source 188 can be preheated using the heat of the housing 164. In some embodiments, the purge fluid from the external fluid source 188 can be used to cool the housing 164 so that it more quickly reaches a temperature where the manifold 110 can be handled by an operator, technician, or the like. It is to be appreciated that one or more temperature sensors 190 can be disposed at various locations to ensure that the various components are heated to the appropriate temperatures. It is to be appreciated that the locations and number of the one or more temperature sensors 190 can vary beyond those shown in the figures.

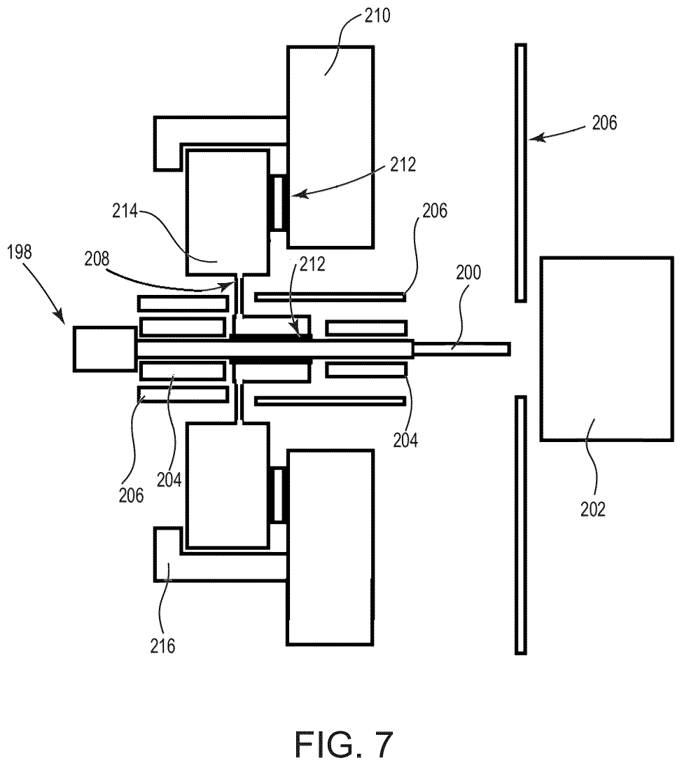

FIG. 7 shows a sectional view of a feedthrough design for a delivery system 150, according to some embodiments. The feedthrough design includes a fitting 198 connected to a gas line 200. The gas line 200 directs source precursor from the fitting 198 to the arc chamber 202. The gas line 200 is adjacent to a heater 204 which is wrapped with insulation 206. The heater 204 and insulation 206 serve to keep the gas line 200 warm and prevent or reduce condensation in the gas line 200. A sleeve 208 surrounds the insulation 206, heater 204, and gas line 200. The feedthrough may further include a source flange 210 with a vacuum seal 212 between the source flange 210 and a mounting plate 214. The source flange 210 and mounting plate 214 may be connected using securing device 216. In some embodiments, the vacuum seal 212 includes an O-ring. In some embodiments, the securing device 216 is a bolt or a clamp.

The feedthrough design allows for effective flow into the arc chamber 202 without condensation or blockage of the gas line 200. The heater 204 and insulation 206 provide heating of the gas line 200. This allows the temperature profile to increase through the flow path of the precursor up to the arc chamber 202. This avoids what would otherwise be a large temperature drop when passing into the vacuum chamber, possibly resulting in condensation of the precursor in the gas line 200. In some embodiments, the gas line 200 and the fitting 198 form the conduit 112.

The described embodiments include the following features in various combinations: the ability to maintain a vacuum seal, heating from ambient side, heating from vacuum side, use of thermally conductive material to transfer heat to places that are impractical to run heaters, insulation and radiant barriers, and use of thermal breaks to create sharp temperature gradients with low heat loss.

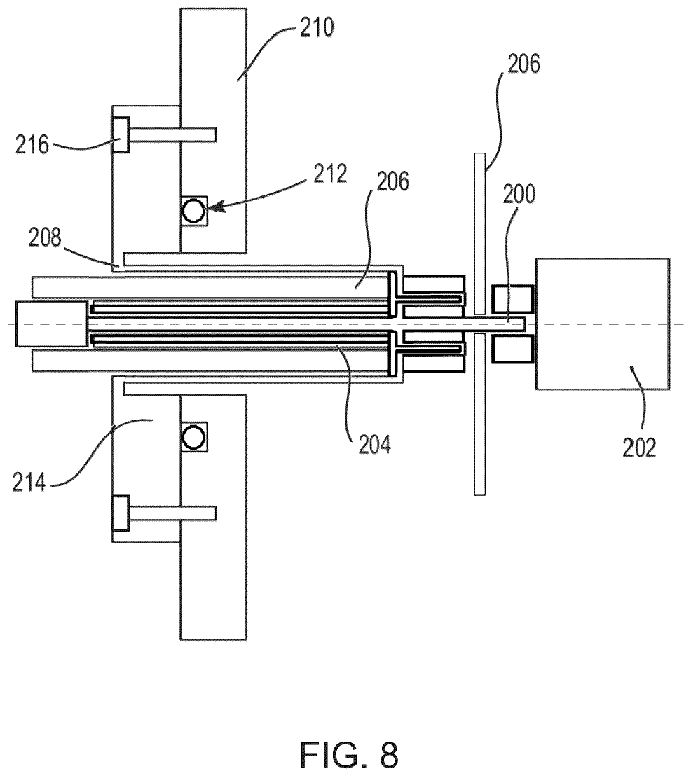

FIG. 8 shows a feedthrough design. In this embodiment, the heater 204 extends beyond the end of the sleeve 208. This embodiment includes thermally conductive material located at various points, for example, in the sleeve 208 near the heater 204. Thermally conductive material also surrounds the gas line 200 near the arc chamber 202.

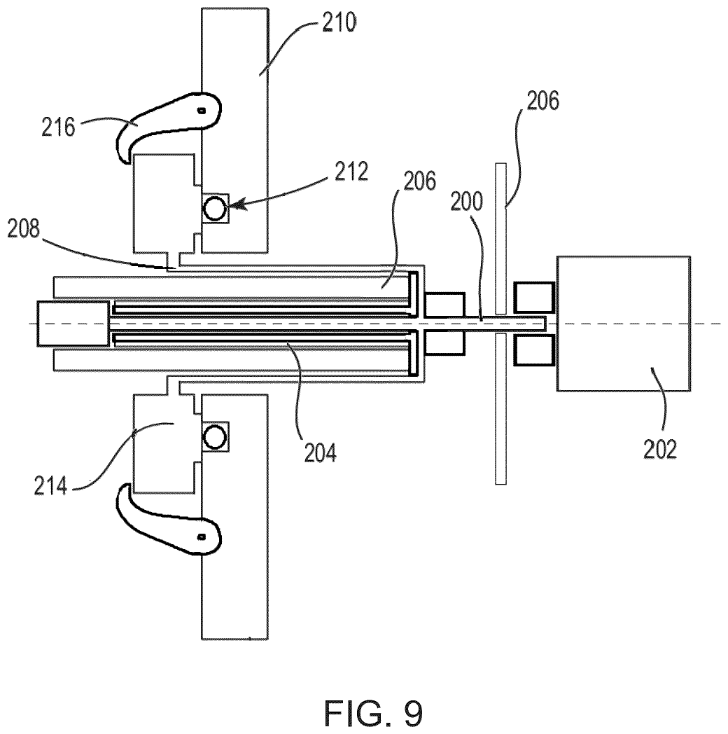

FIG. 9 shows a feedthrough according to an embodiment consistent with this disclosure. The feedthrough of FIG. 9 includes a mounting clamp 216 which secures the mounting flange 214. The source wall 210 is cooled and contacts the mounting flange 214 by reduced contacts which minimize the heat transfer between the source wall 210 and the mounting flange 214. This embodiment utilizes thermally conductive material at the end of the sleeve 208 both inside and outside the sleeve 208. This helps control the temperature of the material flowing in the gas line 200.

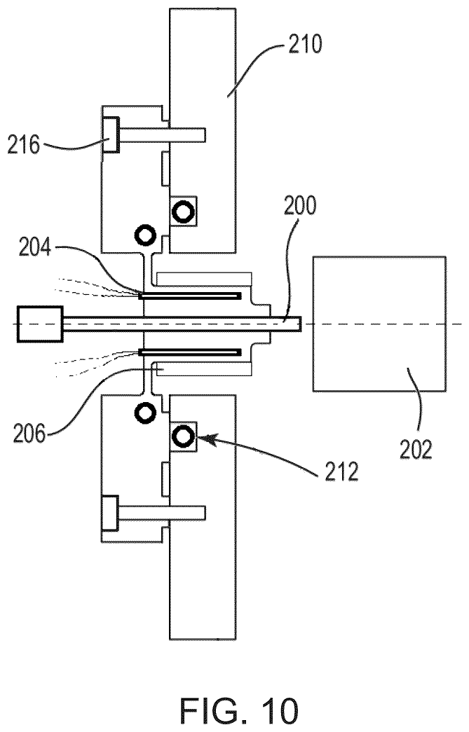

FIG. 10 shows a feedthrough according to an embodiment consistent with this disclosure. The feedthrough of FIG. 10 includes a heater 204 connected to the outside of the feedthrough. The heater 204 is mounted in a thermal block which provides the heat to the gas line 200. The heater 204 is connected to the mounting flange by a thermal break. The thermal block is attached to a radiant barrier which helps reduce energy losses from the block. Near the thermal break, in the mounting flange there may be another heater which serves to minimize the temperature differential across the thermal break. The source wall is cooled and contacts between the mounting flange and source wall are minimized to reduce heat transfer and heat losses across the contacts.

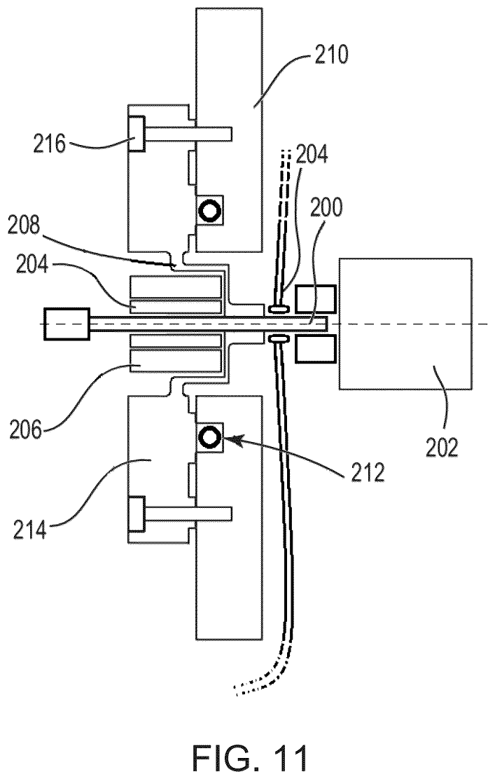

FIG. 11 shows a feedthrough according to an embodiment consistent with this disclosure. This feedthrough includes a heater 204 and insulation 206 on the outside of the feedthrough. This feedthrough also includes a heater on the inside of the chamber located near the gas line 200 and connected to wires which provide electricity. The internal heater is adjacent to a thermally conductive block, which helps distribute the heat from the internal heater. A third heater is located near the thermal break forming the sleeve 208. The third heater helps to minimize the temperature differential across the thermal break and minimize heat losses through the thermal break.

In the various embodiments, a vacuum seal 212 is used to isolate the feedthrough and allow the chamber to be held in vacuum which the exterior (on the left of the figures) is at atmospheric pressure. The vacuum seal 212 may include an O-ring.

In some embodiments, the feedthrough includes active insulation comprising a heater located near a thermal break portion of the sleeve 208. This heater may reduce a temperature difference between one side of the thermal break potion of the sleeve 208 and a second side of the thermal break portion of the sleeve 208.

The terminology used herein is intended to describe embodiments and is not intended to be limiting. The terms “a,” “an,” and “the” include the plural forms as well, unless clearly indicated otherwise. The term “or” is used in the inclusive sense of and/or and not the exclusive sense unless specifically indicated by the usage. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

### Aspects

Any aspect may be combined with any other aspect.

Aspect 1. A delivery system for delivering a vaporized source precursor in ion implantation, comprising:
an assembly comprising:
   a vessel having an interior volume and configured to produce the vaporized source precursor;
   a first heater to heat the vessel; and
   a manifold configured to control the output of the vaporized source precursor to an ion implantation device,
wherein the assembly is configured to be disposed upstream of the source inlet flange.

Aspect 2. The delivery system of aspect 1, wherein the first heater is configured to provide sufficient energy to the interior volume of the vessel to vaporize the source precursor.

Aspect 3. The delivery system of aspect 1 or 2, wherein the manifold is heated.

Aspect 4. The delivery system of any of aspects 1 to 3, wherein the source precursor comprises liquid or solid-phase metal halides, organometallic solids, or combinations thereof.

Aspect 5. The delivery system of any of aspects 1 to 4, wherein the manifold includes a housing, wherein the housing is a block of material including one or more channels formed therein.

Aspect 6. The delivery system of aspect 5, wherein the housing comprises:
a flow control device; and
a pressure sensing device, and
wherein the flow control device and the pressure sensing device are configured to provide a flow rate of the vaporized source precursor from the manifold.

Aspect 7. The delivery system of aspect 6, further comprising:
a thermal control system connected in electronic communication with the flow control device, and/or the pressure sensing device,
wherein the thermal control system is configured to adjust output of the heating component.

Aspect 8. The delivery system of any of aspects 1 to 7, further comprising a first conduit fluidly connecting the vessel and the manifold and a second conduit configured to be fluidly connected to the ion implantation device.

Aspect 9. The delivery system of any of aspects 1 to 8, further comprising a second heater applied to the first conduit and a third heater applied to the second conduit.

Aspect 10. The delivery system of any of aspects 1 to 9, wherein the delivery system is disposed within a gas box.

Aspect 11. The delivery system of any of aspects 1 to 10, wherein the vessel further comprises a valve, wherein the valve is configured to be controlled to operate between a flow enabled state and a flow disabled state.

Aspect 12. The delivery system of any of aspects 1 to 11, further comprising of an additional vessel connected to the manifold to allow the delivery of precursor material from the additional vessel.

Aspect 13. The delivery system of aspect 12, configured to automatically switch over to the additional vessel.

Aspect 14. The delivery system of aspect 12, configured to deliver a different precursor through the same manifold.

Aspect 15. The delivery system of any of aspects 1 to 14, wherein the vessel further comprises an identifying component and the delivery system further comprises an identifier for the identifying component.

Aspect 16. An ion implantation system comprising:
an ion implantation device;
a gas box connected in fluid communication with the ion implantation device, the gas box configured to deliver a vaporized source precursor to the ion implantation device;
a delivery system disposed in the gas box, wherein the delivery system is configured to provide the vaporized source precursor to the ion implantation device, comprising:
an assembly comprising:
   a vessel having an interior volume and configured to produce the vaporized source precursor;
   a first heater to heat the vessel; and
   a manifold configured to control the output of the vaporized source precursor to an ion implantation device,
wherein the assembly is configured to be disposed upstream of the source inlet flange.

Aspect 17. The ion implantation system of aspect 16, wherein the source precursor is aluminum trichloride (AlCl₃).

Aspect 18. The ion implantation system of aspects 16 or 17, wherein the ion implantation system further comprises a valve, wherein the valve is configured to be controlled to operate between a flow enabled state and a flow disabled state.

Aspect 19. The ion implantation system of any of aspects 16 to 18, wherein the manifold includes a housing, wherein the temperature of the housing is controlled to achieve the vapor pressure required to obtain a desired flowrate.

Aspect 20. The ion implantation system of aspect 19, wherein the housing further comprises:
a flow control device
a pressure sensing device and
wherein the flow control device and the pressure sensing device are configured to provide a flow rate of the vaporized source precursor from the manifold.

Aspect 21. The ion implantation system of any of aspects 16 to 20, wherein the vaporized source precursor is provided at a vapor purity level of at least 99%.

Aspect 22. A feedthrough for providing vaporized precursor to an arc chamber comprising:
a gas line conducting vaporized precursor to the arc chamber,
a heating system to heat the gas line to reduce or prevent condensation of the vaporized precursor on an inside surface of the gas line through an actively cooled plate into the arc chamber of an implant tool, and
a support surrounding the gas line to support the gas line and maintain vacuum inside the arc chamber.

Aspect 23. The feedthrough of aspect 22, further comprising insulation around the gas line.

Aspect 24. The feedthrough of aspect 23, further comprising a sleeve over the insulation, wherein the sleeve is part of the support and maintains vacuum inside the arc chamber.

Aspect 25. The feedthrough of any of aspects 22 to 24, further comprising a thermally conductive sleeve around the gas line or support to better transfer and evenly heat the gas line.

Aspect 26. The feedthrough of any of aspects 22 to 24, further comprising a temperature sensor.

Aspect 27. The feedthrough of any of aspects 22 to 25, further comprising a vacuum seal on the plate against a portion of a vacuum chamber.

Aspect 28. A method of providing a vaporized precursor to an ion implantation device comprising,
heating a vessel to a first temperature sufficient to vaporize the precursor inside the vessel;
heating a manifold to a second temperature sufficient to prevent condensation of the vaporized precursor in the manifold,
heating a gas line to a third temperature sufficient to prevent condensation of the vaporized precursor in the gas line; and
flowing vaporized precursor from the vessel to the manifold to the gas line to the ion implantation device.

Aspect 29. The method of aspect 28, wherein the gas line is a feedthrough of aspect 22.

Aspect 30. The method of aspect 28 or 29, further comprising measuring the first temperature with a first temperature sensor, measuring the second temperature with a second temperature sensor, and measuring the third temperature with a third temperature sensor.

Aspect 31. The method of any of aspects 28 to 30, wherein the first temperature is not greater than the second temperature or the third temperature.

1. A delivery system for delivering a vaporized source precursor in ion implantation, comprising:
an assembly comprising:
a vessel having an interior volume and configured to produce the vaporized source precursor;
a first heater to heat the vessel; and
a manifold configured to control the output of the vaporized source precursor to an ion implantation device,
wherein the assembly is configured to be disposed upstream of the source inlet flange.

2. The delivery system of claim 1, wherein the first heater is configured to provide sufficient energy to the interior volume of the vessel to vaporize the source precursor.

3. The delivery system of claim 1, wherein the manifold is heated.

4. The delivery system of claim 1, wherein the source precursor comprises liquid or solid-phase metal halides, organometallic solids, or combinations thereof.

5. The delivery system of claim 1, wherein the manifold includes a housing, wherein the housing is a block of material including one or more channels formed therein.

6. The delivery system of claim 5, wherein the housing comprises:
a flow control device; and
a pressure sensing device, and
wherein the flow control device and the pressure sensing device are configured to provide a flow rate of the vaporized source precursor from the manifold.

7. The delivery system of claim 6, further comprising:
a thermal control system connected in electronic communication with the flow control device, and/or the pressure sensing device,
wherein the thermal control system is configured to adjust output of the heating component.

8. The delivery system of claim 1, further comprising a first conduit fluidly connecting the vessel and the manifold and a second conduit configured to be fluidly connected to the ion implantation device.

9. The delivery system of claim 8, further comprising a second heater applied to the first conduit and a third heater applied to the second conduit.

10. The delivery system of claim 1, wherein the delivery system is disposed within a gas box.

11. The delivery system of claim 1, wherein the vessel further comprises a valve, wherein the valve is configured to be controlled to operate between a flow enabled state and a flow disabled state.

12. The delivery system of claim 1, further comprising of an additional vessel connected to the manifold to allow the delivery of precursor material from the additional vessel.

13. The delivery system of claim 12, configured to automatically switch over to the additional vessel.

14. The delivery system of claim 12, configured to deliver a different precursor through the same manifold.

15. The delivery system of claim 1, wherein the vessel further comprises an identifying component and the delivery system further comprises an identifier for the identifying component.

16. An ion implantation system comprising:
an ion implantation device;
a gas box connected in fluid communication with the ion implantation device, the gas box configured to deliver a vaporized source precursor to the ion implantation device;
a delivery system disposed in the gas box, wherein the delivery system is configured to provide the vaporized source precursor to the ion implantation device, comprising:
an assembly comprising:
a vessel having an interior volume and configured to produce the vaporized source precursor;
a first heater to heat the vessel; and
a manifold configured to control the output of the vaporized source precursor to an ion implantation device,
wherein the assembly is configured to be disposed upstream of the source inlet flange.

17. The ion implantation system of claim 16, wherein the source precursor is aluminum trichloride (AlCl₃).

18. The ion implantation system of claim 16, wherein the ion implantation system further comprises a valve, wherein the valve is configured to be controlled to operate between a flow enabled state and a flow disabled state.

19. The ion implantation system of claim 16, wherein the manifold includes a housing, wherein the temperature of the housing is controlled to achieve the vapor pressure required to obtain a desired flowrate.

20. The ion implantation system of claim 19, wherein the housing further comprises:
a flow control device
a pressure sensing device and
wherein the flow control device and the pressure sensing device are configured to provide a flow rate of the vaporized source precursor from the manifold.

21. The ion implantation system of claim 16, wherein the vaporized source precursor is provided at a vapor purity level of at least 99%.

22. A feedthrough for providing vaporized precursor to an arc chamber comprising:
a gas line conducting vaporized precursor to the arc chamber,
a heating system to heat the gas line to reduce or prevent condensation of the vaporized precursor on an inside surface of the gas line through an actively cooled plate into the arc chamber of an implant tool, and
a support surrounding the gas line to support the gas line and maintain vacuum inside the arc chamber.

23. The feedthrough of claim 22, further comprising insulation around the gas line.

24. The feedthrough of claim 23, further comprising a sleeve over the insulation, wherein the sleeve is part of the support and maintains vacuum inside the arc chamber.

25. The feedthrough of claim 22, further comprising a thermally conductive sleeve around the gas line or support to better transfer and evenly heat the gas line.

26. The feedthrough of claim 22, further comprising a temperature sensor.

27. The feedthrough of claim 22, further comprising a vacuum seal on the plate against a portion of a vacuum chamber.

28. A method of providing a vaporized precursor to an ion implantation device comprising,
heating a vessel to a first temperature sufficient to vaporize the precursor inside the vessel;
heating a manifold to a second temperature sufficient to prevent condensation of the vaporized precursor in the manifold,
heating a gas line to a third temperature sufficient to prevent condensation of the vaporized precursor in the gas line; and
flowing vaporized precursor from the vessel to the manifold to the gas line to the ion implantation device.

29. The method of claim 28, wherein the gas line is a feedthrough of claim 22.

30. The method of claim 28, further comprising measuring the first temperature with a first temperature sensor, measuring the second temperature with a second temperature sensor, and measuring the third temperature with a third temperature sensor.

31. The method of claim 28, wherein the first temperature is not greater than the second temperature or the third temperature.
